(19) United States
(12) Patent Application Publication
(10) Pub. No.: US 2024/0112926 A1
(43) Pub. Date: Apr. 4, 2024

(54) BRUSHES, SYSTEMS, AND METHODS FOR POST-CMP CLEANING OF A SURFACE

(71) Applicant: Illinois Tool Works Inc., Glenview, IL (US)

(72) Inventors: Bradley Scott Withers, El Dorado Hills, CA (US); Corey Alan Hughes, Sacramento, CA (US)

(21) Appl. No.: 18/375,202

(22) Filed: Sep. 29, 2023

Related U.S. Application Data
(60) Provisional application No. 63/413,025, filed on Oct. 4, 2022.

(51) Int. Cl. H01L 21/67; A46B 1/00; A46B 9/00; A46B 11/06; A46B 13/00; A46B 13/02; B08B 1/00; B08B 1/02; B08B 1/04

(52) U.S. Cl. CPC H01L 21/67046; A46B 1/00; A46B 9/005; A46B 11/06; A46B 13/001; A46B 13/02; B08B 1/002; B08B 1/02; B08B 1/04; A46B 2200/3073

(57) ABSTRACT

An example brush for cleaning of a substrate includes: a porous polymeric brush body having one or more contact surfaces for cleaning the substrate, the one or more contact surfaces comprising a microtexture; and a brush support configured to mechanically couple the brush body to an actuator.

### FIELD OF THE DISCLOSURE

The present disclosure relates to substrate-cleaning brushes, and more particularly, to brushes, systems, and methods for post-chemical-mechanical planarization (CMP) cleaning of a surface.

### BACKGROUND

In the semiconductor manufacturing industry and other industries, brushes are used to remove contaminants from surfaces, such as from semiconductor wafers. Depending on the specific application, cleaning of a substrate or surface may also involve delivery of one or more substances (e.g., chemicals, ultra-pure water (UPW), deionized water (DIW), etc.) to the substrate or surface.

Limitations and disadvantages of conventional approaches to conditioning brushes will become apparent to one of skill in the art, through comparison of such approaches with some aspects of the present method and system set forth in the remainder of this disclosure with reference to the drawings.

### SUMMARY

Brushes, systems, and methods for post-CMP cleaning of a surface are disclosed, substantially as illustrated by and described in connection with at least one of the figures, as set forth more completely in the claims.

### BRIEF DESCRIPTION OF THE DRAWINGS

These and/or other aspects will become apparent and more readily appreciated from the following description of the exemplary embodiments, taken in conjunction with the accompanying drawings.

FIGS. 1A, 1B, and 1C are elevation views of example roller brushes and substrates during example cleaning processes, in accordance with aspects of this disclosure.

FIG. 1D illustrates an example cleaning system in which the example brush of FIG. 1B in installed for cleaning the substrate.

FIGS. 2A, 2B, and 2C are more detailed views of example nodules, which may be used to implement the brushes of FIGS. 1B and 1C, including microtexturing.

FIG. 3A is a schematic diagram of an example system to clean a substrate, involving dispensing of multiple fluids via a brush during cleaning of the substrate, in accordance with aspects of this disclosure.

FIG. 3B is a plan view of another example system to clean the substrate during a cleaning process, including another example brush, in accordance with aspects of this disclosure.

FIGS. 4A and 4B are plan views of the brush and substrate of FIG. 3A in different radial and/or angular positions over the surface of the substrate during an example cleaning process.

FIG. 5 illustrates example circular-shaped protrusions including microtexturing that may be used to implement the brush of FIG. 3B.

FIGS. 6A, 6B, and 6C are more detailed views of example nodules, which may be used to implement the brushes of FIGS. 3A and 3B, including microtexturing.

FIG. 7 is a flowchart representative of an example method to clean a substrate using a brush having microtexturing, in accordance with aspects of this disclosure.

The figures are not necessarily to scale. Where appropriate, similar or identical reference numbers are used to refer to similar or identical components.

### DETAILED DESCRIPTION

Various applications and processes may benefit from physical cleaning of a surface. For example, in semiconductor manufacturing, a semiconductor wafer may be cleaned to remove potentially destructive contaminants during one or more stages of fabricating electronic circuits on the wafer. The cleaning can be provided by, for example, a brush that comes in contact with the surface to be cleaned.

To efficiently clean a substrate, disclosed example brushes come into contact with a substrate to be cleaned in the presence of a cleaning chemical. Disclosed example brushes are either mounted or cast directly to rotatable hollow bases or mandrels, with holes that allow water, a chemical, or both to flow through the base or mandrel, into and through the brush body, and onto the substrate or wafer to be cleaned.

Example brushes may be configured with different geometries, including shaped nodules extending from the brush body to make contact with the surface. Example contact surfaces may include sets of nodules having one or more shapes for contact surfaces, and/or may be substantially flat contact surfaces. In some examples, the contact surfaces are configured with microtextures to achieve one or more tribological effects.

As used herein, chemicals or process chemicals may refer to any substance that may be applied via disclosed brushes, including water such as DIW and/or UPW.

Disclosed example brushes for cleaning of a substrate include: a porous polymeric brush body having one or more contact surfaces for cleaning the substrate, the one or more contact surfaces comprising a microtexture; and a brush support configured to mechanically couple the brush body to an actuator.

In some example brushes, the brush body is substantially cylindrical, and the exterior surface of the cylindrical brush body includes the microtexture. In some example brushes, the brush support includes a mandrel configured to rotate the brush about an axis of the substantially cylindrical brush body.

In some example brushes, the brush body is substantially cylindrical and includes a plurality of nodules extending from the cylindrical brush body, the surfaces of the nodules comprising the microtexture. In some such example brushes, an axial dimension of the brush body is greater than a radial dimension.

In some example brushes, the brush body is plate-shaped, having a radial dimension greater than an axial dimension, and a first end surface of the brush body includes the microtexture. In some example brushes, the brush support includes a plate attached to a second end surface opposite the first end surface of the brush body. In some example brushes, the brush body includes a plurality of nodules extending from the first end surface of the brush body, in which the plurality of nodules include the microtexture.

In some example brushes, the microtexturing is structured to provide an enhanced lubrication between the one or more contact surfaces and the substrate, compared with a lack of the microtexturing on the one or more contact surfaces. In some example brushes, the microtexturing is structured to provide an increased friction between the one or more contact surfaces and the substrate, compared with a lack of the microtexturing on the one or more contact surfaces. In some example brushes, the microtexturing is structured to provide an improved cleaning efficiency, compared with a lack of the microtexturing on the one or more contact surfaces.

In some example brushes, the porous polymeric brush body comprises at least one of a polyvinyl acetal foam, a polyurethane foam, a polyolefin foam, a porous fluoropolymers, a silicone foam, a polyester foam, a nylon foam, or a polyacrylic foam. In some example brushes, the porous polymeric brush body is configured to disperse fluid through the microtexture. In some example brushes, the brush body is molded over the brush support, assembled and then mounted on the brush support, or assembled as a sponge-only brush.

In some example brushes, the microtexture includes a plurality of features which are aligned transverse to a direction of motion of the brush body during cleaning. In some example brushes, the microtexture includes a plurality of features having at least one of a rounded shape, a pointed shape, a squared shape, or a linear shape. In some example brushes, the microtexture includes a plurality of features having a constant orientation over a surface of the brush body. In some example brushes, the microtexture includes a plurality of features having a varied orientation over a surface of the brush body.

Disclosed example systems to clean a substrate include: a cleaning brush, having: a porous polymeric brush body having one or more contact surfaces for cleaning the substrate, the one or more contact surfaces comprising a microtexture; and a brush support configured to mechanically support the brush body; and an actuator configured to couple to the brush support and to rotate the brush along an axis of the cleaning brush via the brush support.

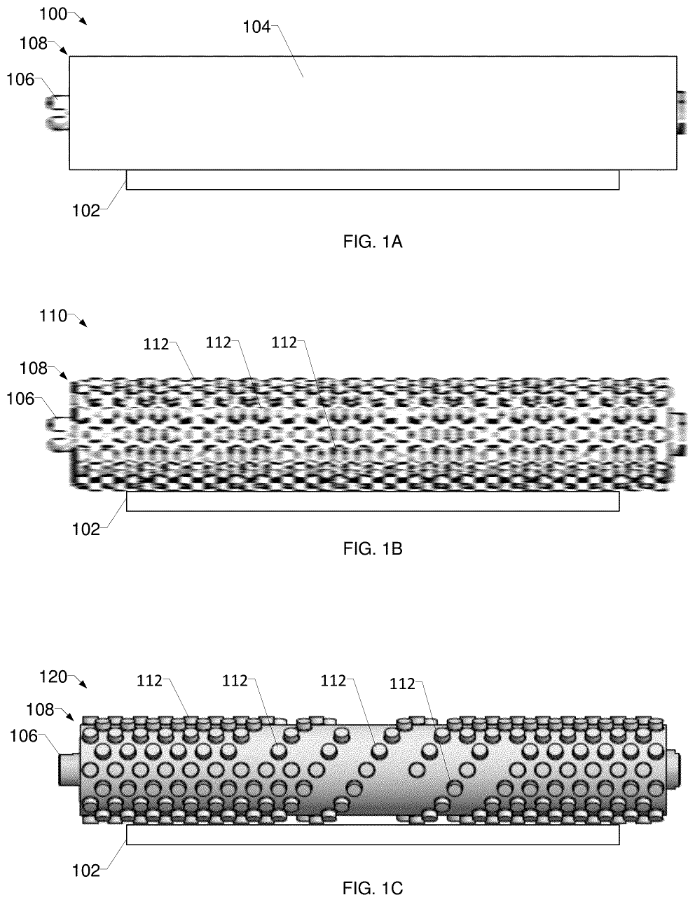

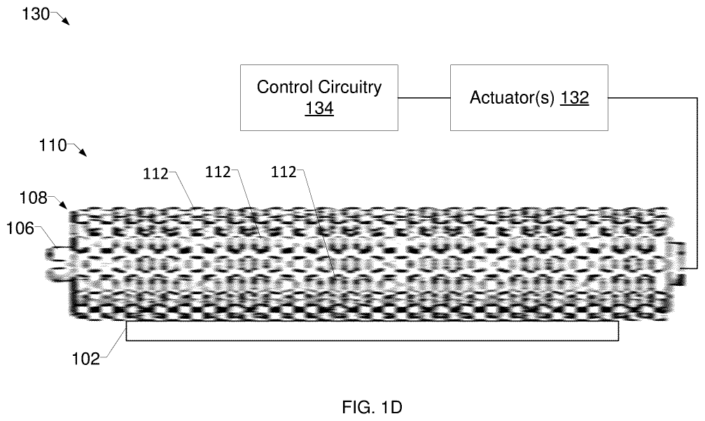

FIG. 1A is an elevation view of an example roller brush 100 during a cleaning process for an example substrate 102. The example roller brush 100 of FIG. 1A performs a post-chemical mechanical planarization (post-CMP, also referred to as post-chemical mechanical polishing), which may involve application of one or more chemicals to the substrate 102. The example roller brush 100 is a cylindrical shape, and has a substantially even contact surface 104, which is rotated to clean the surface of the substrate 102. As used herein, “substantially even” and “substantially flat” refer to a lack of nodules or other protrusions larger than the microtexturing disclosed herein.

FIG. 1B is an elevation view of another example roller brush 110 during a cleaning process for the example substrate 102. In contrast with the example brush 100 of FIG. 1A, the example roller brush 110 is provided (e.g., molded) with nodules 112 which extend from the surface of the roller brush 110. The example nodules 112 of FIG. 1B are regularly spaced over the entirety of the surface of the roller brush 110. However, other shapes, sizes, and/or spacings of the nodules 112 may be used. FIG. 1C is an elevation view of yet another example roller brush 120 during a cleaning process for the example substrate 102. The example brush 120 includes the nodules 112 arranged in a spacing or pattern that may provide a desired effect at the surface of the substrate 102 during cleaning.

Each of the brushes 100, 110, 120 of FIGS. 1A-1C may be supported by an interior mandrel 106, which acts as a brush support which supports a body 108 of the brush 100, 110, 120. The mandrel 106 may be rotated to impart rotation on the body 108 of the brush 100, 110, 120 with respect to the substrate 102. The substrate 102 may be supported on a platen or other support surface. In some examples, the substrate 102 is rotated by the platen in a different rotational direction as the rotation of the brush 100, 110, 120 during the cleaning process. In other examples, the substrate 102 may be conveyed in a linear direction, with or without rotation of the substrate 102.

The example brush body 108 is a porous polymeric foam, which may be molded, machined, constructed using additive manufacturing techniques, and/or otherwise constructed in an annular shape. For example, the brush body 108 may be formed by casting the porous polymeric foam directly on the mandrel 116. In other examples, the porous polymeric foam may be formed as a brush body 108 and then assembled and/or mounted onto the mandrel 116. In some other examples, the brush 100, 110, 120 is a porous polymer brush and manufactured as a sponge-only brush. Example polymeric foams that may be used to implement the brush body 108 include, but are not limited to, polyvinyl acetal foams, polyurethane foams, polyolefin foams, porous fluoropolymers, silicone foams, polyester foams, nylon foams, and/or polyacrylic foams. In the examples of FIGS. 1A-1C, the cylindrical brushes 100, 110, 120 have a longer axial dimension (e.g., length) than the radial dimension (e.g., diameter).

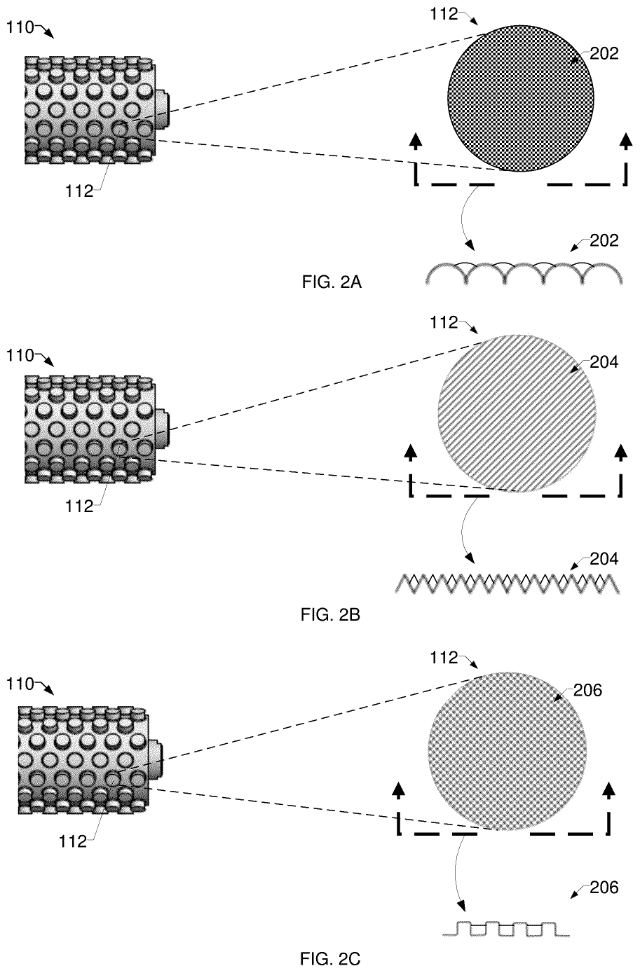

Each of the example brushes 100, 110, 120 of FIGS. 1A-1C is configured to have a microtexture on the contact surfaces of the brushes 100, 110, 120. For example, the microtexture may be provided on even surfaces 104 and/or on the nodules 112 of the brushes 100, 110, 120. As used herein, the term “microtexture” refers to a texture having individual features of less than 1 millimeter (mm) over the contact surface. FIGS. 2A, 2B, and 2C are more detailed views of the example nodules 112, which may be used to implement the brushes 100, 110, 120 of FIGS. 1B and 1C, including microtexturing.

The example surfaces 104 and/or the nodules 112 are formed with microtexturing, which can be applied to the surfaces 104 and/or the nodules 112 (e.g., to the surface of the nodules 112) to affect the cleaning action of the brushes 100, 110, 120 on the substrate 102. The microtexturing of the surfaces 104 and/or the nodules 112 may be performed during molding of the brush body 108, by machining the brush body 108, and/or using any other method of construction or modification.

FIG. 1D illustrates a cleaning system 130 in which the example brush 110 of FIG. 1B in installed for cleaning the substrate 102. The example cleaning system 130 includes one or actuators 132, which are controlled by control circuitry 134 based on the desired cleaning process. For example, the control circuitry 134 may control movement and/or rotation of the brush 110 and/or movement and/or rotation of the substrate 102 by controlling the actuators 132 to move the brush 110 into and/or out of contact with the substrate 102, to move the substrate 102, and/or to rotate the brush 110 along an axis of rotation (e.g., via the mandrel 106).

FIG. 2A illustrates a plan view and an elevation view of an example surface 202 of one of the nodules 112 of FIG. 1B. The example surface 202 has microtexturing including repeating rounded surfaces or microfeatures in a substantially constant pattern. FIG. 2B illustrates a plan view and an elevation view of an example surface 204 of one of the nodules 112 of FIG. 1B. The example surface 204 has microtexturing including pointed surfaces or microfeatures in a substantially constant pattern. FIG. 2C illustrates a plan view and an elevation view of an example surface 206 of one of the nodules 112 of FIG. 1B. The example surface 206 has microtexturing including squared (e.g., flat, stepped) surfaces or microfeatures in a substantially constant pattern. In still other examples, the microtexture may include linear features (e.g., long, linearly shaped features having widths less than 1 mm). Each of the example textures are applied evenly across the surfaces 202-206 of the nodules 112, but may be irregularly applied, and/or applied to different nodules 112 across a length of the brush 110. Any of the example textures may have features having a constant and/or varied orientation over a surface 204 of the brush body 104 or nodules 112. Additionally or alternatively, any of the example textures may have features which are aligned with and/or transverse to a direction of motion of the brush body 104 and/or nodules 112 during cleaning operations.

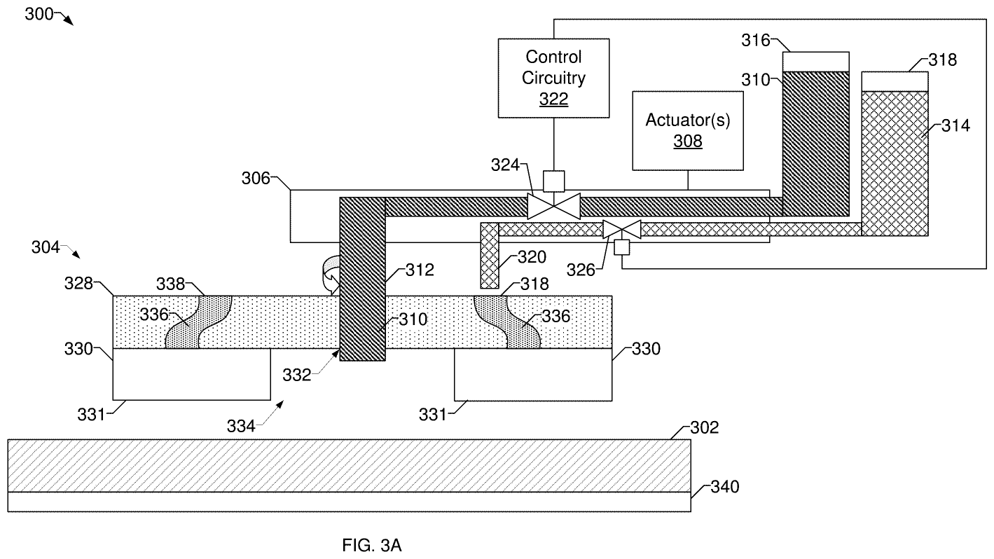

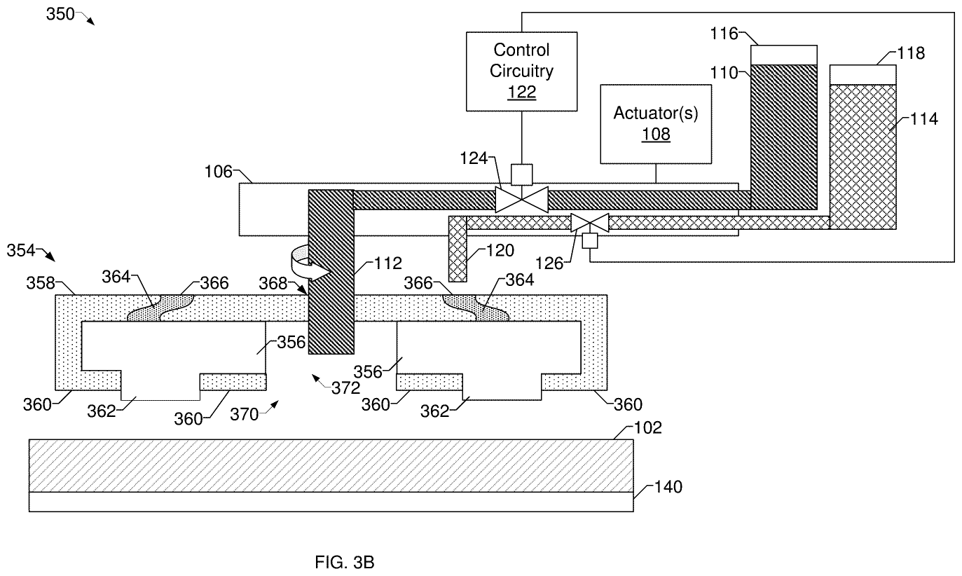

FIG. 3A is a schematic diagram of an example system 300 to clean a substrate 302, involving dispensing of multiple fluids via a brush 304 during cleaning of the substrate 302. The example system 300 includes a support arm 306 coupled to the brush 304. The support arm 306 positions the brush 304 relative to the substrate 302, and couples the brush 304 to one or more actuator(s) 308. The actuator(s) 308 move the brush 304 and/or rotate the brush 304 via the support arm 306 with respect to the substrate 302.

The system 300 and the brush 304 are capable of simultaneously delivering multiple fluids to the brush 304 and/or substrate 302 during cleaning. As described in more detail below, a first chemical 310 may be dispersed to the substrate 302 via a spindle 312, which couples the brush 304 to the support arm 306 (e.g., providing rotational torque to the brush 304 from the actuator(s) 308). A second chemical 314 may be simultaneously dispersed to the substrate 302 via the body of the brush 304, such as by dispersing the second chemical 314 through the brush 304.

The example system 300 includes a first reservoir 316, which stores the first chemical 310 and is in fluid communication with the spindle 312 for dispensing of the first chemical 310. The system 300 also includes a second reservoir 318, which stores the second chemical 314 and is in fluid communication with a dispenser 320 (e.g., a nozzle, a tube, etc.). The first and second reservoirs 316, 318 may have the same or different capacities. The first and second reservoirs 316, 318 may be local or proximate to the system 300 and/or may be facility-based supplies of pressurized chemicals 310, 316 in fluid communication with the support arm 306.

The system 300 includes control circuitry 322 configured to control valves 324, 326. The valves 324, 326 may be controlled to set dispensation rates for the chemicals 310, 314 from the reservoirs 316, 318. The example valves 324, 326 are low power, electronically controlled solenoid valves. However, any other type of electronically controlled valve may be used, taking into account the desired flow rates, power consumption, and/or response times.

The example brush 304 includes an annular plate 328 and an annular brush body 330. The annular plate 328 is attached or bonded to the annular brush body 330, and provides mechanical support and coupling between the brush body 330 and the spindle 312. The brush body 330 is placed into contact with the substrate 302 (e.g., via a contact surface 331 of the brush body 330) to clean and/or polish the substrate 302. The contact surface 331 of the brush body 330 may be non-textured or may include microtexturing and/or patterns as described above with respect to the surface 202 of FIGS. 2A-2C.

The example plate 328 includes an annulus 332. The spindle 312 extends through the annulus 332 to enable delivery of the first chemical 310 to the substrate 302 through the brush 304. The brush body 330 also includes an annulus 334, which is aligned (e.g., overlapping, concentric, etc.) with the annulus of the plate 328. The annuluses 332, 334 are sufficiently large to permit delivery of the first chemical 310 to the substrate 302. In some examples, the annulus 334 of the brush body 330 is sufficiently large to reduce or eliminate chemical interactions between the first chemical 310 and the second chemical 314 within the body of the brush body 330 prior to the chemicals 310, 314 reaching the substrate 302. The annulus 334 of the brush body 330 may also be sufficiently small to increase (e.g., maximize) contact area between the brush body 330 and the substrate 302.

The example brush body 330 is a porous polymeric foam, which may be molded, machined, constructed using additive manufacturing techniques, and/or otherwise constructed in an annular shape. Example polymeric foams that may be used to implement the brush body 330 include, but are not limited to, polyvinyl acetate foams, polyurethane foams, polyolefin foams, porous fluoropolymers, silicone foams, polyester foams, nylon foams, and/or polyacrylic foams.

The plate 328 further includes one or more channel(s) 336, which extend from an inlet 338 of the channels 336 at a top side of the plate 328, to the interface between the plate 328 and the brush body 330. The channel(s) 336 provide fluid delivery from the nozzle 320 to the brush body 330. The nozzle 320 is aligned with the channel(s) 336 to deliver the second chemical 314 to the channel(s) 336. The channels 336 may operate as a secondary reservoir to provide the second chemical 314 directly to the brush body 330.

Because the example brush body 330 is porous, the second chemical 314 disperses through the brush body 330 toward the substrate 302, and eventually reaches the interface between the brush body 330 and the substrate 302 for cleaning. In some examples, the channels 336 are configured to provide substantially even dispersion of the second chemical 314 through the brush body 330, to provide different concentrations of the second chemical 314 at different locations within the brush body 330 or different locations on the surface of the brush body 330, or to focus dispensing of the second chemical 314 at one or more locations on the surface of the brush body 330.

The substrate 302 may be supported on a platen 340 or other support surface. In some examples, the substrate 302 is rotated by the platen 340 in a same or different rotational direction as the rotation of the brush 304 during the cleaning process. In other examples, the substrate 302 may be conveyed in a linear direction, with or without rotation of the substrate 302.

FIG. 3B is a plan view of another example system 350 to clean the substrate 102 during a cleaning process, including another example brush 352. The example system 350 includes the support arm 306, the actuator(s) 308, the spindle 312, the reservoirs 316, 318, the nozzle 320, the control circuitry 322, the valves 324, 326, and the platen 340 of FIG. 3A described above.

The example brush 352 of FIG. 3B includes a brush body 356, a top plate 358, and a bottom plate 360. The top plate 358 may be similar or identical to the top plate 328 of FIG. 3A. In the example of FIG. 3B, the top plate 358 and the bottom plate 360 are connected to provide top and bottom support to the brush body 356. In other examples, the top plate 358 and the bottom plate 360 may be separately connected to the brush body 356 to provide rigidity and/or control chemical dispensation from the brush body 356.

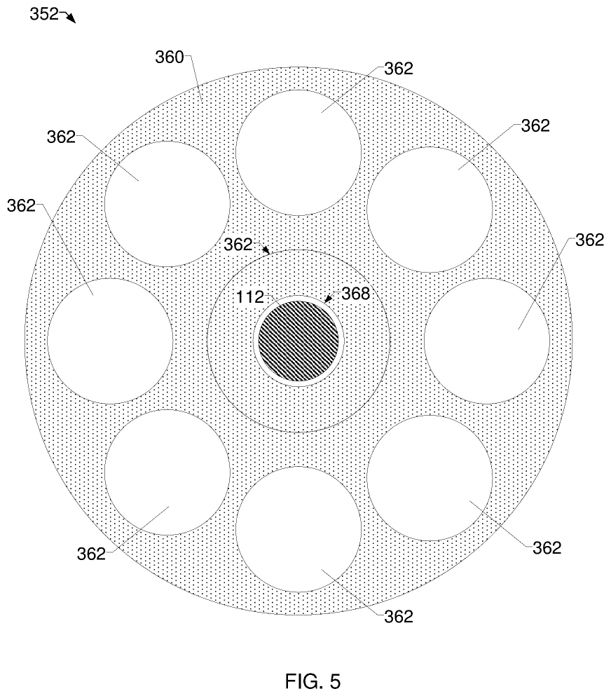

FIG. 5 illustrates example circular-shaped protrusions 362. Different brushes 352 may have different shapes, sizes, and/or distributions of the protrusions 362 over the bottom surface of the brush. While the example brush 352 includes the respective bottom plates 360, in other examples the brush may include protrusions or nodules while omitting the bottom plate 360.

The top plate 358 includes channels 364 having inlets 366. The channels 364 and inlets 366 may be similar or identical to the example channels 336 and inlets 338 of the brush 304 of FIG. 3A. However, as discussed above, the channels 364 and/or inlets 366 may have and desired shape, size, and/or quantity to receive, disperse, and dispense the second chemical 314 to the substrate 302. An annulus 368 of the top plate 358 is concentric with an annulus 370 of the bottom plate 360 and an annulus 372 of the brush body 356, and allows delivery of the first chemical 310 to the substrate 302 via the spindle 312.

While the foregoing examples include one or more plates on the exterior of the porous polymeric brush body, in some other examples the brush body is overmolded or printed over an interior plate or other structure. In some such examples, the interior plate or structure implements the channels, inlets, and/or interfaces with the brush body to disperse the second chemical 314 from the nozzle 320. The interior plate or structure may include, and/or be configured to connect to, the spindle 312 for actuation of the brush and dispensation of the first chemical 310 via an annulus in the porous polymeric brush body.

In the examples of FIGS. 3A and 3B, the brush body has a radial dimension larger than the axial dimension, and the end surface(s) are provided with microtexturing.

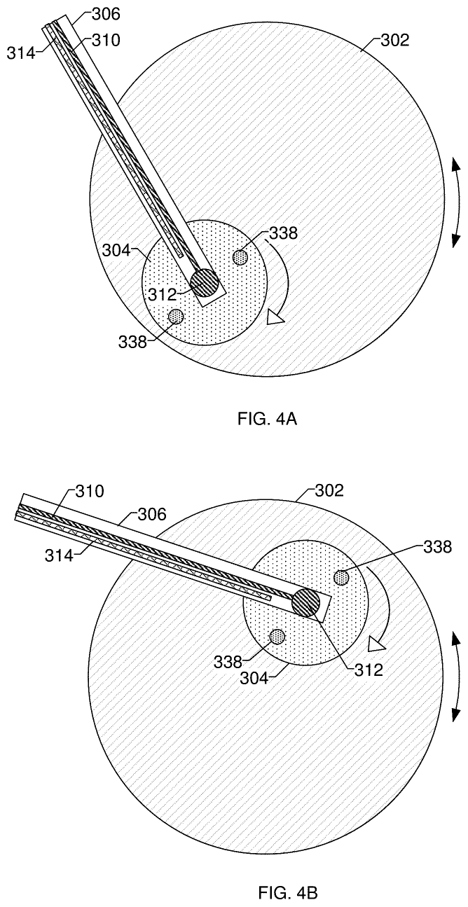

FIGS. 4A and 4B are plan views of the brush 304 and substrate 302 of FIG. 3 in different radial and/or angular positions over the surface of the substrate 302 during an example cleaning process. The example brush 304 is supported, positioned, and rotated via the support arm 306. The support arm 306 also delivers the chemicals 310, 314 to the brush 304 (e.g., to the annulus 332, 334 of the brush 304, to the inlets 338 channels 336).

The example substrate 302 may rotate in either direction, or remain stationary, while the support arm 306 moves the brush 304 over the surface of, and in contact with, the substrate 302. The support arm 306 further controls rotation of the brush 304 via the spindle 312. The radial position of the brush 304 on the substrate 302 is controlled by moving the support arm 306 with respect to the substrate 302, while the angular position of the brush 304 with respect to the surface of the substrate 302 is controlled by rotating the substrate 302. However, in other examples, the support arm 306 may be capable of positioning the brush 304 at any angular and/or radial position on the substrate 302. The support arm 306 may further control the distance between the brush 304 and the substrate 302, and/or the pressure applied to the substrate 302 by the brush 304.

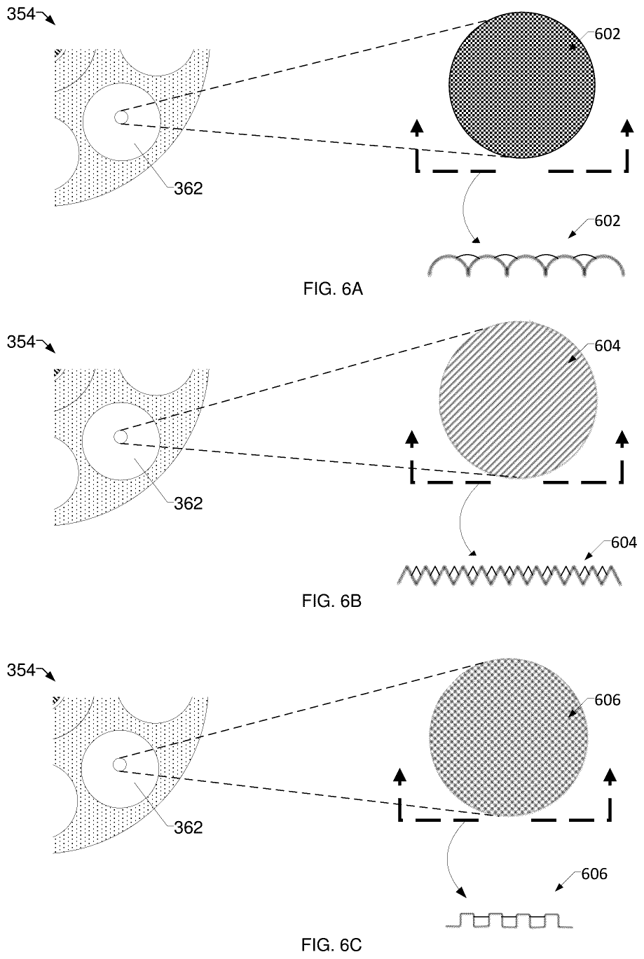

FIG. 6A illustrates a plan view and an elevation view of an example surface 602 of one of the nodules 362 of FIG. 3B. The example surface 602 has microtexturing including repeating rounded surfaces or microfeatures in a substantially constant pattern, which may be similar or identical to the example microtexturing of FIG. 2A. FIG. 6B illustrates a plan view and an elevation view of an example surface 604 of one of the nodules 362 of FIG. 3B. The example surface 604 has microtexturing including pointed surfaces or microfeatures in a substantially constant pattern, which may be similar or identical to the example microtexturing of FIG. 2B. FIG. 6C illustrates a plan view and an elevation view of an example surface 606 of one of the nodules 362 of FIG. 3B. The example surface 606 has microtexturing including squared (e.g., flat, stepped) surfaces or microfeatures in a substantially constant pattern, which may be similar or identical to the example microtexturing of FIG. 2C. In still other examples, the microtexture may include linear features (e.g., long, linearly shaped features having widths less than 1 mm). Each of the example textures are applied evenly across the surface 602-606 of the nodules 362, but may be irregularly applied, and/or applied to different nodules 362 of the brush 354. Any of the example textures may have features having a constant and/or varied orientation over a surface 606 of the brush 304 or nodules 362. Additionally or alternatively, any of the example textures may have features which are aligned with and/or transverse to a direction of motion of the brush 304 and/or nodules 362 during cleaning operations. In some examples, the microtexturing described in relation to the nodules 362 is also applicable to the contact surface 331 of the brush body 330 described in FIG. 3A, which may be untextured or include microtexturing and/or patterns as described in FIGS. 2A-2C and 6A-6C.

While example microtextures and patterns are illustrated in FIGS. 2A-2C and 6A-6C, the microfeature shapes, concentrations or densities of features, microfeature sizes, microfeature depths, and/or any other geometrical aspect of the microfeatures may be modified to obtain the desired cleaning effects, unique tribological functions (e.g., enhanced lubrication, increased friction, improved cleaning efficiency), and/or different dispensation effects of one or more chemicals applied to the substrate 102, 302. Different portions of the brush body 108, 330 and/or different nodules 112, 362 may have different microtexturing features or properties. The same or different microtexturing may be used with different shapes of the nodules 112, 362. The features and/or properties of the microtexturing may be selected based on the types of chemicals used during the cleaning process, such as to promote or mitigate intermixing of the different chemicals 310, 314 of FIGS. 3A-3B on the surface of the substrate 102, 302.

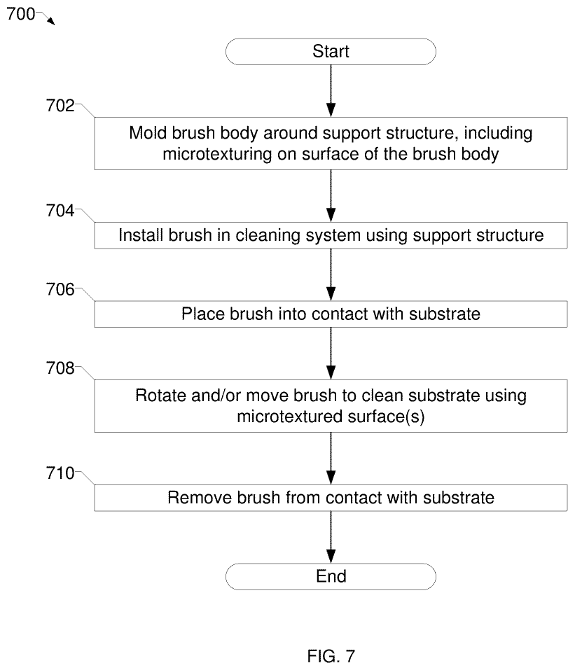

FIG. 7 is a flowchart representative of an example method 700 to clean a substrate using a brush having microtexturing. The method 700 may be performed using, for example, any of the brushes 100, 110, 120 of FIGS. 1A-1C or the brushes 304, 354 of FIGS. 3A and 3B.

Block 702 involves molding a brush body (e.g., the brush body 108 of FIGS. 1A-1C) around a support structure (e.g., the mandrel 106 of FIGS. 1A-1C), such that the brush body 108 includes microtexturing on a surface of the brush body 108. In some other examples, block 702 may involve molding a brush body (e.g., the brush body 330, 356 of FIGS. 3A, 3B) separately to include the microtexturing, and attaching the brush body 330, 356 to a support structure (e.g., the annular plate 328 of FIG. 3A, the top plate 358 and bottom plate 360 of FIG. 3B). In some other examples, the brush body is a sponge-only brush made of porous polymer. The microtexturing may be designed or selected to provide desired cleaning effects, tribological functions (e.g., enhanced lubrication, increased friction, improved cleaning efficiency), and/or dispensation effects of one or more chemicals.

Block 704 involves installing the brush in a cleaning system using the support structure. For example, the brushes 100, 110, 120 may be installed in a corresponding cleaning system which rotates the brush 100, 110, 120 via the mandrel 106. In other examples, the brushes 304, 354 may be installed in a cleaning system 300, 350 via the support structures 328, 358, 360 for dispensation of chemicals via the brush 304, 354.

Block 706 involves placing the brush into contact with a substrate 102, 302. For example, the substrate 102, 302 may be conveyed into contact with the brush 100, 110, 120, 304, 354, and/or the brush 100, 110, 120, 304, 354 may be moved into contact with the substrate 102, 302.

Block 708 involves rotating and/or moving the brush 100, 110, 120, 304, 354 to clean the substrate 102, 302 using the microtextured surface(s) of the brush 100, 110, 120, 304, 354. For example, the surface 104, 331 and/or nodules 112, 362 include microtextured surfaces that provide desired effects during the cleaning operation. For example, the control circuitry 134, 322 may control respective actuator(s) 132, 308 to rotate and/or move the brush 100, 110, 120, 304, 354. In some examples, the rotation of the brush may be controlled based on the microtexture(s) present on the installed brush 100, 110, 120, 304, 354. For example, the control circuitry 134, 322 may receive an input representative of the microtextures(s) that are on the installed brush 100, 110, 120, 304, 354 and adapt movement speed, movement direction, rotational speed, and/or rotational direction of the brush 100, 110, 120, 304, 354 to improve the effectiveness of the microtexture(s) during the cleaning procedure.

Block 710 involves removing the brush 100, 110, 120, 304, 354 from contact with the substrate 102, 302 (e.g., at the conclusion of a cleaning process). For example, the substrate 102, 302 may be conveyed out of contact with the brush 100, 110, 120, 304, 354, and/or the brush 100, 110, 120, 304, 354 may be moved out of contact with the substrate 102, 302.

The example method 700 then ends.

The example control circuitry 134, 322 includes at least one controller or processor that controls the operations of the system 100, 300, 350. The control circuitry 134, 322 receives and processes multiple inputs associated with the performance and demands of the system 100, 300, 350. The control circuitry 134, 322 may include one or more microprocessors, such as one or more “general-purpose” microprocessors, one or more special-purpose microprocessors and/or ASICS, and/or any other type of processing device. For example, the control circuitry 134, 322 may include one or more digital signal processors (DSPs). The example control circuitry 134, 322 may further include one or more storage device(s) (e.g., ROM, flash memory, a hard drive, and/or any other suitable optical, magnetic, and/or solid-state storage medium, and/or a combination thereof) and one or more memory device(s) (e.g., volatile and/or non-volatile memory).

The present methods and systems may be realized in hardware, software, and/or a combination of hardware and software. The present methods and/or systems may realize, for example, the control circuitry 134, 322 in a centralized fashion in at least one computing system, or in a distributed fashion where different elements are spread across several interconnected computing systems. Any kind of computing system or other apparatus adapted for carrying out the methods described herein is suited. A typical combination of hardware and software may include a general-purpose computing system with a program or other code that, when being loaded and executed, controls the computing system such that it carries out the methods described herein. Another typical implementation may comprise one or more application specific integrated circuit or chip. Some implementations may comprise a non-transitory machine-readable (e.g., computer readable) medium (e.g., FLASH memory, optical disk, magnetic storage disk, or the like) having stored thereon one or more lines of code executable by a machine, thereby causing the machine to perform processes as described herein. As used herein, the term “non-transitory machine-readable medium” is defined to include all types of machine readable storage media and to exclude propagating signals.

As utilized herein the terms “circuits” and “circuitry” refer to physical electronic components (i.e. hardware) and any software and/or firmware (“code”) which may configure the hardware, be executed by the hardware, and or otherwise be associated with the hardware. As used herein, for example, a particular processor and memory may comprise a first “circuit” when executing a first one or more lines of code and may comprise a second “circuit” when executing a second one or more lines of code. As utilized herein, “and/or” means any one or more of the items in the list joined by “and/or.” As an example, “x and/or y” means any element of the three-element set {(x), (y), (x, y)}. In other words, “x and/or y” means “one or both of x and y”. As another example, “x, y, and/or z” means any element of the seven-element set {(x), (y), (z), (x, y), (x, z), (y, z), (x, y, z)}. In other words, “x, y and/or z” means “one or more of x, y and z”. As utilized herein, the term “exemplary” means serving as a non-limiting example, instance, or illustration. As utilized herein, the terms “e.g.” and “for example” set off lists of one or more non-limiting examples, instances, or illustrations. As utilized herein, circuitry is “operable” to perform a function whenever the circuitry comprises the necessary hardware and code (if any is necessary) to perform the function, regardless of whether performance of the function is disabled or not enabled (e.g., by a user-configurable setting, factory trim, etc.).

While the present method and/or system has been described with reference to certain implementations, it will be understood by those skilled in the art that various changes may be made and equivalents may be substituted without departing from the scope of the present method and/or system. In addition, many modifications may be made to adapt a particular situation or material to the teachings of the present disclosure without departing from its scope. Therefore, the present method and/or system are not limited to the particular implementations disclosed. Instead, the present method and/or system will include all implementations falling within the scope of the appended claims, both literally and under the doctrine of equivalents.

What is claimed is:

1. A brush for cleaning of a substrate, the brush comprising:
a porous polymeric brush body having one or more contact surfaces for cleaning the substrate, the one or more contact surfaces comprising a microtexture; and
a brush support configured to mechanically couple the brush body to an actuator.

2. The brush as defined in claim 1, wherein the brush body is substantially cylindrical, and an exterior surface of the cylindrical brush body comprises the microtexture.

3. The brush as defined in claim 2, wherein the brush support comprises a mandrel configured to rotate the brush about an axis of the cylindrical brush body.

4. The brush as defined in claim 1, wherein the brush body is substantially cylindrical and comprises a plurality of nodules extending from the cylindrical brush body, the plurality of nodules comprising the contact surfaces, and the contact surfaces of the plurality of nodules comprising the microtexture.

5. The brush as defined in claim 4, wherein an axial dimension of the brush body is greater than a radial dimension.

6. The brush as defined in claim 1, wherein the brush body is plate-shaped, having a radial dimension greater than an axial dimension, and a first end surface of the brush body comprises the microtexture.

7. The brush as defined in claim 6, wherein the brush support comprises a plate attached to a second end surface opposite the first end surface of the brush body.

8. The brush as defined in claim 6, wherein the brush body comprises a plurality of nodules extending from the first end surface of the brush body, the plurality of nodules comprising the microtexture.

9. The brush as defined in claim 1, wherein the microtexture is structured to provide an enhanced lubrication between the one or more contact surfaces and the substrate, compared with a lack of the microtexturing on the one or more contact surfaces.

10. The brush as defined in claim 1, wherein the microtexture is structured to provide an increased friction between the one or more contact surfaces and the substrate, compared with a lack of the microtexturing on the one or more contact surfaces.

11. The brush as defined in claim 1, wherein the microtexture is structured to provide an improved cleaning efficiency, compared with a lack of the microtexturing on the one or more contact surfaces.

12. The brush as defined in claim 1, wherein the porous polymeric brush body comprises at least one of a polyvinyl acetal foam, a polyurethane foam, a polyolefin foam, a porous fluoropolymer, a silicone foam, a polyester foam, a nylon foams, or a polyacrylic foam.

13. The brush as defined in claim 1, wherein the porous polymeric brush body is configured to disperse fluid through the microtexture.

14. The brush as defined in claim 1, wherein the brush body is molded over the brush support, assembled and then mounted on the brush support, or assembled as a sponge-only brush.

15. The brush as defined in claim 1, wherein the microtexture comprises a plurality of features which are aligned in a direction of motion of the brush body during cleaning.

16. The brush as defined in claim 1, wherein the microtexture comprises a plurality of features which are aligned transverse to a direction of motion of the brush body during cleaning.

17. The brush as defined in claim 1, wherein the microtexture comprises a plurality of features having at least one of a rounded shape, a pointed shape, a squared shape, or a linear shape.

18. The brush as defined in claim 1, wherein the microtexture comprises a plurality of features having a constant orientation over a surface of the brush body.

19. The brush as defined in claim 1, wherein the microtexture comprises a plurality of features having a varied orientation over a surface of the brush body.

20. A system to clean a substrate, the system comprising:
a cleaning brush, comprising:
a porous polymeric brush body having one or more contact surfaces for cleaning the substrate, the one or more contact surfaces comprising a microtexture; and
a brush support configured to mechanically support the brush body; and
an actuator configured to couple to the brush support and to rotate the brush along an axis of the cleaning brush via the brush support.
